(19) United States
(12) Patent Application Publication
(10) Pub. No.: US 2024/0282284 A1
(43) Pub. Date: Aug. 22, 2024

(54) SOUND WAVE DELIVERY STRUCTURE

(71) Applicant: CENTER FOR ADVANCED META-MATERIALS, Daejeon (KR)

(72) Inventors: Jae Hwa LEE, Daejeon (KR); Tae In CHOI, Daejeon (KR); Hak Joo LEE, Daejeon (KR); Chee Young JOH, Changwon-si, Gyeongsangnam-do (KR)

(73) Assignee: CENTER FOR ADVANCED META-MATERIALS, Daejeon (KR)

(21) Appl. No.: 18/571,245

(22) PCT Filed: Nov. 1, 2022
(86) PCT No.: PCT/KR2022/016867

§ 371 Date: Dec. 17, 2023

(30) Foreign Application Priority Data
Nov. 24, 2021 (KR) 10-2021-0163514
Nov. 24, 2021 (KR) 10-2021-0163515

(51) Int. Cl. G10K 11/02; G01S 7/521; G01S 15/06

(52) U.S. Cl. CPC G10K 11/02; G01S 7/521; G01S 15/06; H10N 30/101; G10K 2200/11

(57) ABSTRACT

A sound wave delivery structure of the present invention comprises unit structure cells each formed to have a cubic shape and comprising a column portion formed on a region corresponding to sides, and a space portion formed in an internal region surrounded by the column portion. There are a plurality of unit structure cells which are successively arranged in a first direction, in which sound waves are delivered, and a second direction crossing the first direction.

### TECHNICAL FIELD

The present invention relates to a sound wave delivery structure, and more specifically, to a sound wave delivery structure installed in a sound transducer for detecting a position of a target using sound waves in water.

### BACKGROUND ART

A sound transducer for detecting a position of a target using sound waves in water functions to convert an input electrical signal into a sound signal, radiate the sound signal in water, and receive a signal reflected back from the target in an active mode, and convert the sound signal radiated from the target into an electrical signal in a passive mode.

Generally, a sound transducer for transmitting high-output sound waves employs a Tonpilz type transducer. This is because sound waves are generated as a change in pressure occurs in water, which is a medium, due to the Tonpilz type sound transducer of which a length changes in a longitudinal direction, and maximized sound waves are transmitted or the ability to receive external sound sources or reflected sound waves is improved by using the Tonpilz type sound transducer in a resonance frequency range.

Typically, the Tonpilz type transducer includes a piezoelectric element, a front weight disposed on a front surface of the piezoelectric element and for radiating the vibration of the piezoelectric element as a sound signal, and a rear weight disposed on a rear surface of the piezoelectric element and for increasing energy radiated when the front weight radiates the sound signal. By using the front weight and the rear weight in a specific frequency range, the Tonpilz type transducer can reduce an electrical impedance by reducing a length of a piezoelectric part and function as a heat radiator when the front weight and the rear weight are driven at high power.

Meanwhile, a mechanical characteristic impedance required for the front weight is a function of a density and a sound speed, the sound speed is a function of a density and a modulus of elasticity, and there is no commercial material that satisfies the characteristic impedance. Therefore, in order to meet the characteristic impedance, a method of forming the front weight by appropriately mixing a fine spherical metallic body with epoxy has been conventionally used. However, this method has problems in that it is difficult to implement homogeneous physical properties and productivity is low.

In particular, in order to achieve the broadband performance of a Tonpilz type ultrasonic sensor with a single resonance, a specific equivalent mechanical quality factor of 2 to 3 should be satisfied in a resonance mode, and it is known that there is no low-density commercial metal material to satisfy a theoretical mechanical quality factor.

In addition, a multi-resonant Tonpilz transducer has a problem in that components, such as a front weight, passive compliant elements, and a plurality of central masses, are required, thereby making a configuration and a shape complex, and it is difficult to design an optimal resonant frequency.

### Technical Problem

In order to solve the problems, the present invention is directed to providing a sound wave delivery structure that may be manufactured to have a required specific impedance.

In addition, in order to solve the problems, the present invention is directed to providing a sound wave delivery structure capable of easily generating a required broadband bandwidth through multiple resonances.

The objects of the present invention are not limited to the above-described objects, and other objects that are not mentioned will be able to be clearly understood by those skilled in the art to which the present invention pertains from the following description.

### Technical Solution

In order to achieve the objects, a first embodiment of the present invention provides a sound wave delivery structure including a unit structure cell formed in a cubic shape and including column portions formed in areas corresponding to sides thereof, and a space portion formed in an inner area surrounded by the column portions, wherein the unit structure cell is provided as a plurality of unit structure cells and disposed consecutively in a first direction in which sound waves are delivered and a second direction crossing the first direction.

In the embodiment of the present invention, the unit structure cell may be formed in a rectangular parallelepiped shape.

In the embodiment of the present invention, the unit structure cell may further include an auxiliary column portion connecting two separated corners and disposed to cross the space portion.

In the embodiment of the present invention, the unit structure cell may further include a flat portion formed to connect two corners selected from each surface to a center of the space portion.

In the embodiment of the present invention, the sound wave delivery structure may further include a first contact surface in contact with a vibrating part that generates sound waves, wherein the first contact surface may be formed in the form of a filled surface without an empty space.

In the embodiment of the present invention, a second contact surface of the sound wave delivery structure formed at an opposite side of the first contact surface and in contact with an external medium may be formed in the form of a filled surface without an empty space.

In order to achieve the objects, a second embodiment of the present invention provides a sound wave delivery structure including a unit structure cell formed in a three-dimensional shape and including column portions formed in areas corresponding to sides thereof, and a space portion formed in an inner area surrounded by the column portions, wherein the unit structure cell is provided as a plurality of unit structure cells and disposed consecutively in a first direction in which sound waves are delivered and a second direction crossing the first direction, and partitioned into a central portion formed within a predetermined distance from a center axis, and an edge portion provided at a position far from the central portion with respect to the center axis, and a unit structure cell disposed at the central portion and a unit structure cell disposed at the edge portion among the plurality of unit structure cells are different.

In the embodiment of the present invention, the unit structure cell may be formed in a rectangular parallelepiped shape.

In the embodiment of the present invention, a cross-sectional area of the column portion of the unit structure cell disposed at the central portion may be larger than a cross-sectional area of the column portion of the unit structure cell disposed at the edge portion.

In the embodiment of the present invention, the unit structure cell disposed at the central portion and the unit structure cell disposed at the edge portion may have different sizes.

In the embodiment of the present invention, a first contact surface formed between the sound wave delivery structure and a vibrating part disposed at one side of the sound wave delivery structure may be formed in the form of a filled surface without an empty space.

In the embodiment of the present invention, a second contact surface formed between the sound wave delivery structure and an external medium provided at the other side of the sound wave delivery structure may be formed in the form of a filled surface without an empty space.

In the embodiment of the present invention, the unit structure cell may further include an auxiliary column portion connecting two separated corners and disposed to cross the space portion.

In the embodiment of the present invention, the unit structure cell may further include a flat portion formed to connect two corners selected from each surface to a center of the space portion.

Meanwhile, in order to achieve the objects, a third embodiment of the present invention provides a sound wave delivery structure including a unit structure cell formed in a three-dimensional shape and including column portions formed in areas corresponding to sides thereof, and a space portion formed in an inner area surrounded by the column portions, wherein an intermediate mass, a front weight, and a connecting rod connecting the intermediate mass to the front weight, which are arranged in a first direction in which sound waves are delivered, are formed, and the intermediate mass, the connecting rod, and the front weight are configured by consecutively arranging the unit structure cells in the first direction and a second direction crossing the first direction.

In the embodiment of the present invention, the unit structure cell may be formed in a rectangular parallelepiped shape.

In the embodiment of the present invention, a third contact surface formed between the intermediate mass and a vibrating part disposed at one side of the intermediate mass may be formed in the form of a filled contact surface without an empty space.

In the embodiment of the present invention, a fourth contact surface formed between the front weight and an external medium provided at the other side of the front weight may be formed in the form of a filled contact surface without an empty space.

In the embodiment of the present invention, the unit structure cell may further include an auxiliary column portion connecting two separated corners and disposed to cross the space portion.

In the embodiment of the present invention, the unit structure cell may further include a flat portion formed to connect two corners selected from each surface to a center of the space portion.

### Advantageous Effects

According to the embodiment of the present invention, it is possible to easily manufacture the sound wave delivery structure through the 3D printing technology as long as the shape of the sound wave delivery structure, which may implement the required impedance, for example, the length and the thickness of the column portion of the unit structure cell, the volume of the space portion, the number of arranged unit structure cells, and the like are calculated through theoretical calculation.

In addition, according to the embodiment of the present invention, the sound wave delivery structure can generate different frequency bands so that the sound waves of the broadband frequency with the bandwidth including two frequency bands are generated.

It should be understood that the effects of the present invention are not limited to the above-described effects and include all effects inferrable from the configuration of the invention described in the detailed description or claims of the present invention.

### DESCRIPTION OF DRAWINGS

FIG. 1 is a view illustrating an example in which a sound wave delivery structure according to a first embodiment of the present invention is installed in an underwater sound sensor.

FIG. 2 is a view illustrating the sound wave delivery structure according to the first embodiment of the present invention.

FIG. 3 is a front view illustrating the sound wave delivery structure in FIG. 2.

FIG. 4 is an image illustrating tensile compressive load characteristics of the sound wave delivery structure in FIG. 2.

FIG. 5 is a view illustrating a first contact surface and a second contact surface of the sound wave delivery structure in FIG. 2.

FIG. 6 is a view illustrating a first modified example of the sound wave delivery structure in FIG. 2.

FIG. 7 is a front view illustrating the sound wave delivery structure in FIG. 6.

FIG. 8 is a view illustrating a second modified example of the sound wave delivery structure in FIG. 2.

FIG. 9 is a front view illustrating the sound wave delivery structure in FIG. 8.

FIG. 10 is an image illustrating the characteristic of a modulus of elasticity of the sound wave delivery structure in FIG. 8.

FIG. 11 is a view illustrating an example in which a sound wave delivery structure according to a second embodiment of the present invention is installed in an underwater sound sensor.

FIG. 12 is a view illustrating the sound wave delivery structure according to the second embodiment of the present invention.

FIG. 13 is a view illustrating a modified example of the sound wave delivery structure in FIG. 12.

FIG. 14 is a view for describing that a broadband frequency is generated from the sound wave delivery structure in FIG. 12.

FIG. 15 is an image illustrating tensile compressive load characteristics of the sound wave delivery structure in FIG. 12.

FIG. 16 is a view illustrating a first contact surface and a second contact surface of the sound wave delivery structure in FIG. 12.

FIG. 17 is a view illustrating a first modified example of unit structure cells of the sound wave delivery structure in FIG. 12.

FIG. 18 is a front view illustrating the unit structure cells in FIG. 17.

FIG. 19 is a view illustrating a second modified example of the unit structure cells of the sound wave delivery structure in FIG. 12.

FIG. 20 is a front view illustrating the unit structure cells in FIG. 19.

FIG. 21 is an image illustrating the characteristic of a modulus of elasticity of the sound wave delivery structure in FIG. 19.

FIG. 22 is a view illustrating an example in which a sound wave delivery structure according to a third embodiment of the present invention is installed in an underwater sound sensor.

FIG. 23 is a view for describing that a broadband frequency is generated from the sound wave delivery structure according to the third embodiment of the present invention.

### MODE FOR INVENTION

Hereinafter, the present invention will be described with reference to the accompanying drawings. However, the present invention may be implemented in various different forms and is not limited to embodiments described herein. In addition, in order to clearly describe the present invention in the drawings, components irrelevant to the description have been omitted, and throughout the specification, similar components have been denoted by similar reference numerals.

Throughout the specification, when a first component is described as being“connected to (joined to, in contact with, or coupled to)” a second component, this includes not only a case in which the first component is “directly connected” to the second component, but also a case in which the first component is “indirectly connected” to the second component with a third component interposed therebetween. In addition, when the first component is described as “including,” the second component, this means that the first component may further include the third component rather than precluding the third component unless especially stated otherwise.

The terms used in the specification are only used to describe specific embodiments and are not intended to limit the present invention. The singular expression includes the plural expression unless the context clearly dictates otherwise. In the specification, it should be understood that terms such as “comprise” or “have” are intended to specify that a feature, a number, a step, an operation, a component, a part, or a combination thereof described in the specification is present, but do not preclude the possibility of the presence or addition of one or more other features, numbers, steps, operations, components, parts, or combinations thereof.

Hereinafter, embodiments of the present invention will be described in detail with reference to the accompanying drawings.

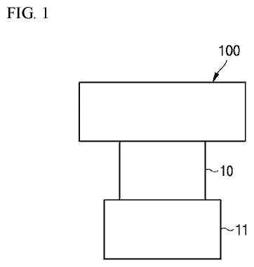

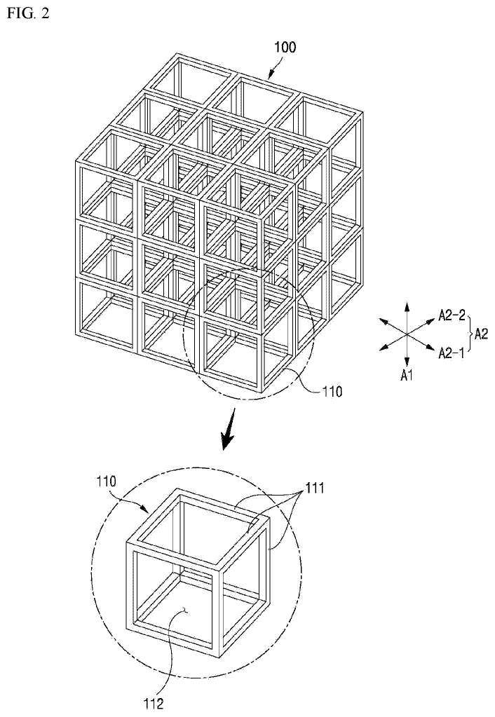

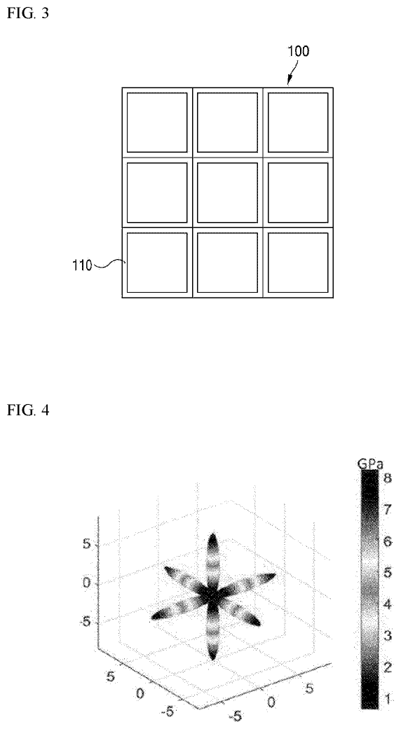

FIG. 1 is a view illustrating an example in which a sound wave delivery structure according to a first embodiment of the present invention is installed in an underwater sound sensor, FIG. 2 is a view illustrating the sound wave delivery structure according to the first embodiment of the present invention, and FIG. 3 is a front view illustrating the sound wave delivery structure in FIG. 2.

As illustrated in FIGS. 1 to 3, a sound wave delivery structure 100 may be provided on a front surface of a vibrating part 10 to deliver the vibration of the vibrating part 10 as sound waves. The vibrating part 10 may be a piezoelectric element, and the piezoelectric element may vibrate when a voltage is applied to generate sound waves and convert the sound waves into electrical signals when receiving the sound waves. A rear weight 11 may be disposed on a rear surface of the vibrating part 10.

The sound wave delivery structure 100 may include a plurality of unit structure cells 110. The unit structure cell 110 may be formed in a three-dimensional shape, preferably, in a rectangular parallelepiped shape, and more preferably, in a cubic shape.

In addition, the plurality of unit structure cells 110 may be arranged consecutively. Specifically, the unit structure cells 110 may be arranged consecutively in a first direction A1 in which sound waves are delivered. In addition, the unit structure cells 110 may be arranged consecutively in a second direction A2 crossing the first direction A1. The second direction A2 may include a 2-1 direction A2-1 and a 2-2 direction A2-2 that are perpendicular to each other so that the unit structure cells 110 in a rectangular parallelepiped shape may be arranged consecutively. Since the first direction A1, the 2-1 direction A2-1, and the 2-2 direction A2-2 may be perpendicular to each other, the plurality of unit structure cells 110 may be three-dimensionally arranged consecutively. Since a length of one side of the unit structure cell 110 may be as small as several to hundreds of μm, although the unit structure cell 110 is formed in a rectangular parallelepiped shape, the sound wave delivery structure 100 may be formed in various shapes such as a cylindrical shape.

In addition, in the present embodiment, the unit structure cell 110 may have column portions 111 and a space portion 112.

The column portions 111 may be formed in areas corresponding to sides of the unit structure cell 110. In addition, the space portion 112 may be formed in an inner area surrounded by the column portions 111. The unit structure cell 110 according to the present embodiment may have a three-dimensional truss-lattice structure.

Since the sound wave delivery structure 100 may be manufactured by using a 3D printing technology, the sound wave delivery structure 100 may be easily manufactured as various three-dimensional structures.

The sound wave delivery structure 100 may be used as a front weight of a Tonpilz type ultrasonic sensor. As described above, since there is no commercial material that satisfies the mechanical characteristic impedance required for the front weight, a method of forming the front weight by appropriately mixing a fine spherical metallic body with epoxy has been conventionally used to meet the characteristic impedance. However, this method has problems in that it is difficult to implement homogeneous physical properties and productivity is low.

However, the sound wave delivery structure 100 according to the present invention may be easily manufactured through the 3D printing technology as long as a shape of the sound wave delivery structure 100, which may implement a required impedance, for example, a length and a thickness of the column portion 111 of the unit structure cell 110, a volume of the space portion 112, the number of arranged unit structure cells 110, and the like are calculated through theoretical calculation. Therefore, a customized front weight to satisfy various required impedance conditions may be acquired. In particular, in order to achieve the broadband performance of a Tonpilz type ultrasonic sensor with a single resonance, a specific equivalent mechanical quality factor of 2 to 3 should be satisfied in a resonance mode, and the sound wave delivery structure 100 according to the present invention may be acquired to satisfy the theoretical mechanical quality factor as much as possible.

FIG. 4 is an image illustrating tensile compressive load characteristics of the sound wave delivery structure in FIG. 2.

As illustrated in FIG. 4, it can be seen that the unit structure cell 110 according to the present embodiment has a very high modulus of elasticity in an axial direction and a great rigidity against a tensile compressive load. Therefore, the sound wave delivery structure 100 including the unit structure cells 110 is less affected by bending vibration of the front weight, and performance can be effectively achieved in an environment in which an axial tensile compressive load is large.

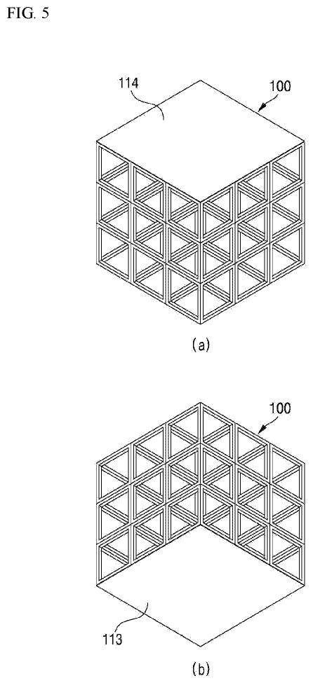

FIG. 5 is a view illustrating a first contact surface and a second contact surface of the sound wave delivery structure in FIG. 2.

As illustrated in FIG. 5, the sound wave delivery structure 100 may have a first contact surface 113 coming into contact with the vibrating part 10 that generates sound waves. Based on a proceeding direction of a sound generated from the vibrating part 10, the first contact surface 113 may be the rear surface of the sound wave delivery structure 100.

It is preferable that the first contact surface 113 is formed in the form of a filled surface without an empty space. Therefore, since not only the compressive deformation of the first contact surface 113 can be prevented but also the sound wave delivery structure 100 and the vibrating part 10 may be in closer contact with each other, the sound wave delivery structure 100 may effectively deliver the vibration of the vibrating part 10 as sound waves.

The first contact surface 113 may be formed at the same height while connecting column portions at rear end sides of the plurality of unit structure cells disposed at a portion in contact with the vibrating part 10 in the sound wave delivery structure 100 or formed to further protrude rearward than the column portions at the rear end sides of the plurality of unit structure cells to have a thickness.

A fastening member (e.g., a bolt) connecting the sound wave delivery structure 110 to the vibrating part 10 may be directly coupled to the first contact surface 113.

In addition, the sound wave delivery structure 100 may have a second contact surface 114 formed at an opposite side of the first contact surface 113 and in contact with an external medium. Based on the proceeding direction of the sound generated from the vibrating part 10, the second contact surface 114 may be a front surface of the sound wave delivery structure 100. In addition, the external medium may be water.

It is preferable that the second contact surface 114 is formed in the form of a filled surface without an empty space. Therefore, since watertightness can be improved, a radiating area can be increased, an axial displacement of a radiating surface can be increased, and the external medium can be in closer contact, it is possible to maximize the radiated sound energy and effectively deliver the sound waves radiated from the sound wave delivery structure 100 to the external medium. In addition, the second contact surface 114 can prevent foreign substances included in the external medium from flowing into the sound wave delivery structure 100.

The second contact surface 114 may be formed at the same height while connecting column portions at front end sides of the plurality of unit structure cells disposed on a front surface portion of the sound wave delivery structure 100 or formed to further protrude forward than the column portions at the front end sides of the plurality of unit structure cells to have a thickness.

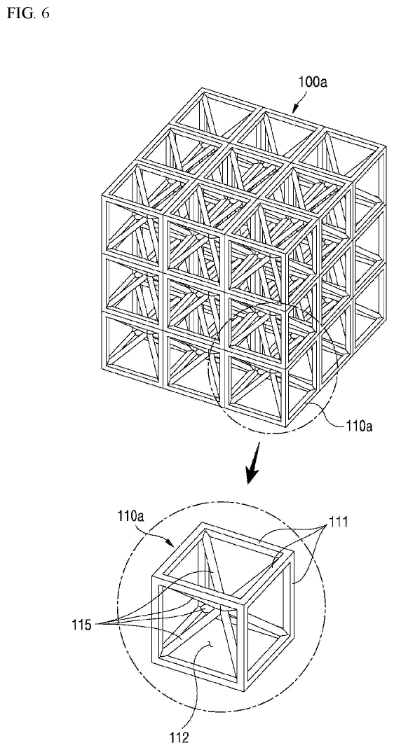

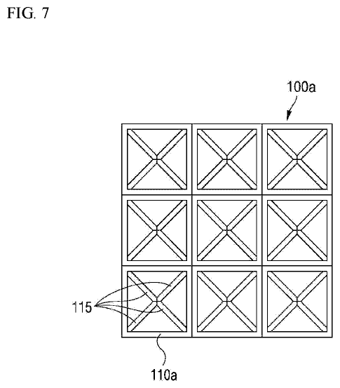

FIG. 6 is a view illustrating a first modified example of the sound wave delivery structure in FIG. 2, and FIG. 7 is a front view illustrating the sound wave delivery structure in FIG. 6. In the present embodiment, since the unit structure cell may have a different configuration from the unit structure cell described with reference to FIGS. 1 to 5 and other configurations are the same, repeated contents are omitted as much as possible.

As illustrated in FIGS. 6 and 7, a unit structure cell 110a of a sound wave delivery structure 100a according to the present embodiment may further include auxiliary column portions 115. In other words, the unit structure cell 110a according to the present embodiment may have a three-dimensional truss-lattice structure with the auxiliary column portions 115 in the space portion 112.

The auxiliary column portion 115 may connect two separated corners and may be disposed to cross the space portion 112. Since the unit structure cell 110a may be reinforced in a diagonal direction by the auxiliary column portions 115, the sound wave delivery structure 100a including the auxiliary column portions 115 may reinforce rigidity against a shear force and a bending load.

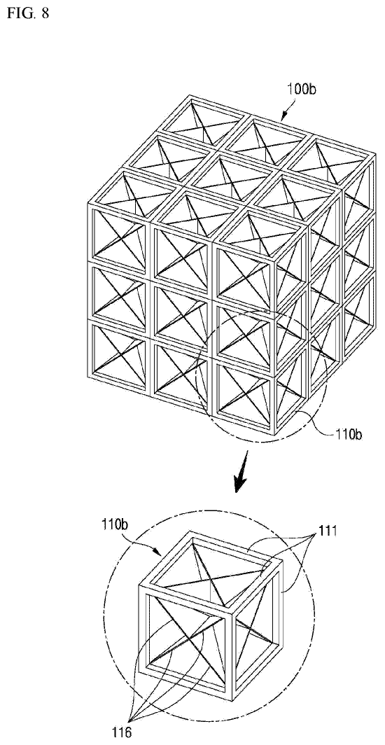

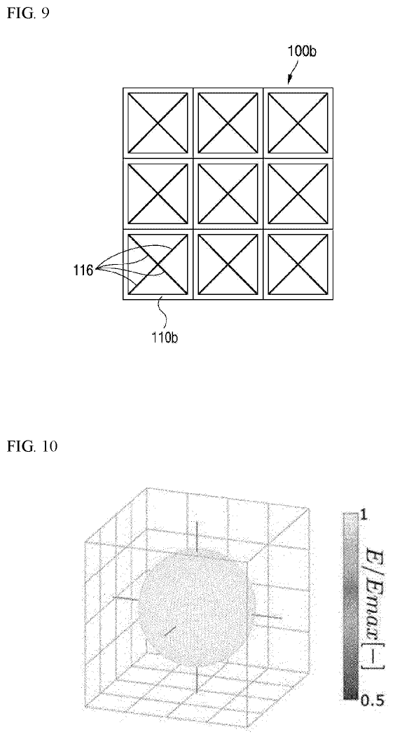

FIG. 8 is a view illustrating a second modified example of the sound wave delivery structure in FIG. 2, FIG. 9 is a front view illustrating the sound wave delivery structure in FIG. 8, and FIG. 10 is an image illustrating the characteristic of a modulus of elasticity of the sound wave delivery structure in FIG. 8. In the present embodiment, since the unit structure cell may have a different configuration from the unit structure cell described with reference to FIGS. 1 to 5 and other configurations are the same, repeated contents are omitted as much as possible.

As illustrated in FIGS. 8 to 10, a unit structure cell 110b of a sound wave delivery structure 100b according to the present embodiment may further include a flat portion 116.

The flat portion 116 may be formed by connecting two corners selected from each surface of the unit structure cell 110b to a center of the space portion. The unit structure cell 110b according to the present embodiment may have a three-dimensional plate-lattice structure.

Since the sound wave delivery structure 100b according to the present embodiment may have isotropic elasticity, the rigidity against the shear force or the bending load may be larger. Therefore, the sound wave delivery structure 100b including the unit structure cell 110b not only has a large axial tensile compressive load of the front weight, but also the performance can be effectively achieved even in an environment in which the influence of the bending vibration is large.

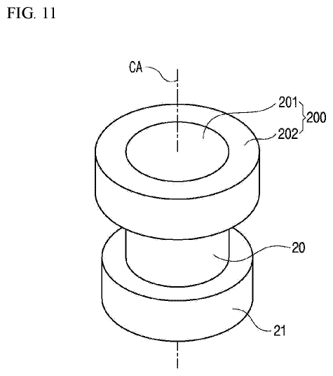

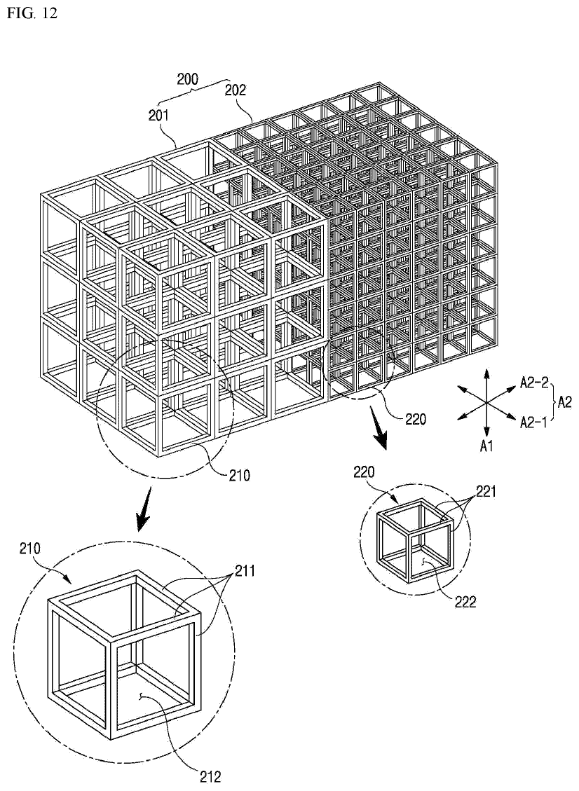

FIG. 11 is a view illustrating an example in which a sound wave delivery structure according to a second embodiment of the present invention is installed in an underwater sound sensor, and FIG. 12 is a view illustrating the sound wave delivery structure according to the second embodiment of the present invention.

As illustrated in FIGS. 11 and 12, a sound wave delivery structure 200 may be provided on a front surface of a vibrating part 20 to deliver the vibration of the vibrating part 20 as sound waves. The vibrating part 20 may be a piezoelectric element, and the piezoelectric element may vibrate when a voltage is applied to generate sound waves and convert the sound waves into electrical signals when receiving the sound waves. A rear weight 21 may be disposed on a rear surface of the vibrating part 20.

The sound wave delivery structure 200 may include a plurality of unit structure cells 210 and 220. The unit structure cells 210 and 220 may be formed in a three-dimensional shape, preferably, in a rectangular parallelepiped shape, and more preferably, in a cubic shape.

In addition, the plurality of unit structure cells 210 and 220 may be arranged consecutively. Specifically, the unit structure cells 210 and 220 may be arranged consecutively in a first direction A1 in which sound waves are delivered. In addition, the unit structure cells 210 and 220 may be arranged consecutively in a second direction A2 crossing the first direction A1. The second direction A2 may include a 2-1 direction A2-1 and a 2-2 direction A2-2 that are perpendicular to each other so that the unit structure cells 210 and 220 in a rectangular parallelepiped shape may be arranged consecutively. Since the first direction A1, the 2-1 direction A2-1, and the 2-2 direction A2-2 may be perpendicular to each other, the plurality of unit structure cells 210 and 220 may be three-dimensionally arranged consecutively. Since lengths of one sides of the unit structure cells 210 and 220 may be as small as several to hundreds of μm, although the unit structure cells 210 and 220 are formed in a rectangular parallelepiped shape, the sound wave delivery structure 200 may be formed in various shapes such as a cylindrical shape.

The sound wave delivery structure 200 may be partitioned into a central portion 201 and an edge portion 202. The central portion 201 may be formed within a predetermined distance from a central axis CA, and the edge portion 202 may be provided at a position far from the central portion 201 with respect to the central axis CA. The edge portion 202 may be provided consecutively on an outer circumferential surface of the central portion 201.

In addition, all the unit structure cells of the central portion 201 and the edge portion 202 may each have column portions and a space portion.

Referring to the unit structure cell 210 disposed at the central portion 201, the column portions 211 may be formed in areas corresponding to the sides of the unit structure cell 210. In addition, the space portion 212 may be formed in an inner area surrounded by the column portions 211.

In addition, referring to the unit structure cell 220 disposed at the edge portion 202, the column portions 221 may be formed in areas corresponding to the sides of the unit structure cell 220, and the space portion 222 may be formed in an inner area surrounded by the column portions 221. The unit structure cells 210 and 220 according to the present embodiment may have a three-dimensional truss-lattice structure.

Among the plurality of unit structure cells 210 and 220 of the sound wave delivery structure 200, the unit structure cell 210 disposed at the central portion 201 and the unit structure cell 220 disposed at the edge portion 202 may differ from each other.

Specifically, the unit structure cell 210 disposed at the central portion 201 and the unit structure cell 220 disposed at the edge portion 202 may have different sizes. In other words, as illustrated in FIG. 2, the unit structure cell 210 disposed at the central portion 201 may be formed to be larger than the unit structure cell 220 disposed at the edge portion 202.

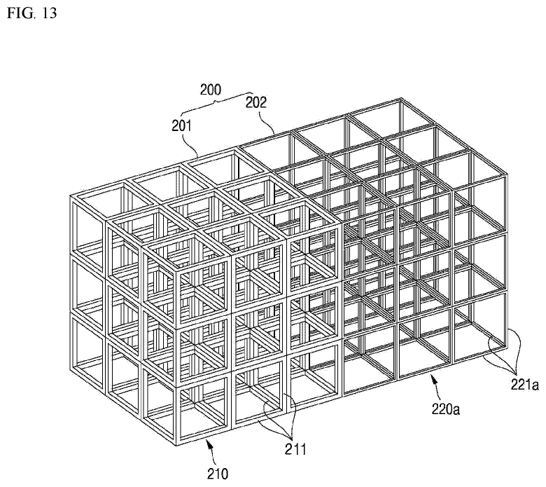

In addition, FIG. 13 is a view illustrating a modified example of the sound wave delivery structure in FIG. 12, and as illustrated in FIG. 13, the column portion 211 of the unit structure cell 210 disposed at the central portion 201 may be formed to have a larger cross-sectional area than a column portion 221a of the unit structure cell 220a disposed at the edge portion 202. In other words, the unit structure cell 210 disposed at the central portion 201 and the unit structure cell 220a disposed at the edge portion 202 may be formed to have the same size, and the column portion 211 of the unit structure cell 210 disposed at the central portion 201 may be formed to have a larger thickness than the column portion 221a of the unit structure cell 220a disposed at the edge portion 202.

Alternatively, conversely in some cases, the unit structure cell disposed at the central portion 201 may be formed to be smaller than the unit structure cell disposed at the edge portion 202, and the column portion of the unit structure cell disposed at the central portion 201 may be formed to be thinner than the column portion of the unit structure cell disposed at the edge portion 202.

Therefore, since the unit structure cell 210 disposed at the central portion 201 and the unit structure cells 220 and 220a disposed at the edge portion 202 may have different densities, different frequency bands may be generated from the central portion 201 and the edge portion 202. In addition, therefore, it is possible to generate sound waves of a broadband frequency with a bandwidth including two frequency bands.

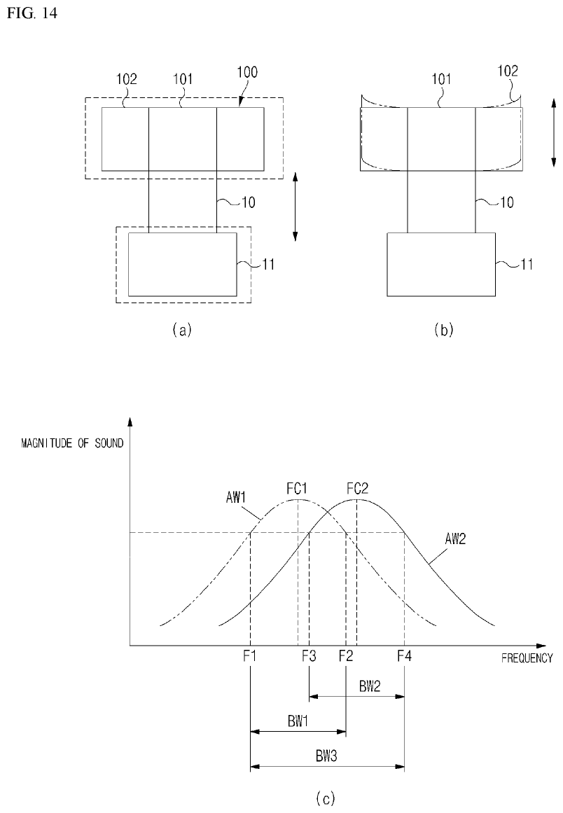

FIG. 14 is a view for describing that a broadband frequency is generated from the sound wave delivery structure in FIG. 12.

As illustrated in FIG. 14, as the vibrating part 20 vibrates, when a first sound wave AW1 radiated by generating a primary resonance from the sound wave delivery structure 200 and the rear weight 21 (see FIG. 14A) may have, for example, a center frequency FC1 and have a first bandwidth BW1 between a first frequency F1 and a second frequency F2, and a second sound wave AW2 radiated by generating a secondary resonance from the edge portion 202 (see FIG. 14B) does not slightly match the first sound wave AW1, that is, for example, when the second sound wave AW2 has a center frequency FC2 and has a second bandwidth BW2 between a third frequency F3 and a fourth frequency F4, a broadband band BW3 between the first frequency F1 and the fourth frequency F4 may be generated (see FIG. 14C). The sound waves of the broadband frequency generated through multiple resonances can help, for example, to obtain the effect of expanding a detection area of a submarine.

Since the sound wave delivery structure 200 may be manufactured by using the 3D printing technology, a boundary portion between the central portion 201 and the edge portion 202 may be naturally connected so that the central portion 201 and the edge portion 202 may be manufactured integrally, and the sound wave delivery structure 200 may also be easily manufactured as various three-dimensional structures.

The sound wave delivery structure 200 may be used as a front weight of a Tonpilz type ultrasonic sensor. As described above, since there is no commercial material that satisfies the mechanical characteristic impedance required for the front weight, a method of forming the front weight by appropriately mixing a fine spherical metallic body with epoxy has been conventionally used to meet the characteristic impedance. However, this method has problems in that it is difficult to implement homogeneous physical properties and productivity is low.

However, the sound wave delivery structure 200 according to the present invention may be easily manufactured through the 3D printing technology as long as a shape of the sound wave delivery structure 200, which may implement a required impedance, for example, a length and a thickness of the column portions 211 and 221 of the unit structure cell 210 and 220, a volume of the space portions 212 and 222, the number of arranged unit structure cells 210 and 220, and the like are calculated through theoretical calculation. Therefore, a customized front weight to satisfy various required impedance conditions may be acquired. In particular, in order to achieve the broadband performance of the Tonpilz type ultrasonic sensor through multiple resonances, a plurality of frequency bands for implementing the bandwidth should be satisfied, and the sound wave delivery structure 200 according to the present invention may be manufactured to also satisfy the plurality of theoretical frequency bands as much as possible and thus implemented as the sound wave delivery structure for a multi-resonance sensor.

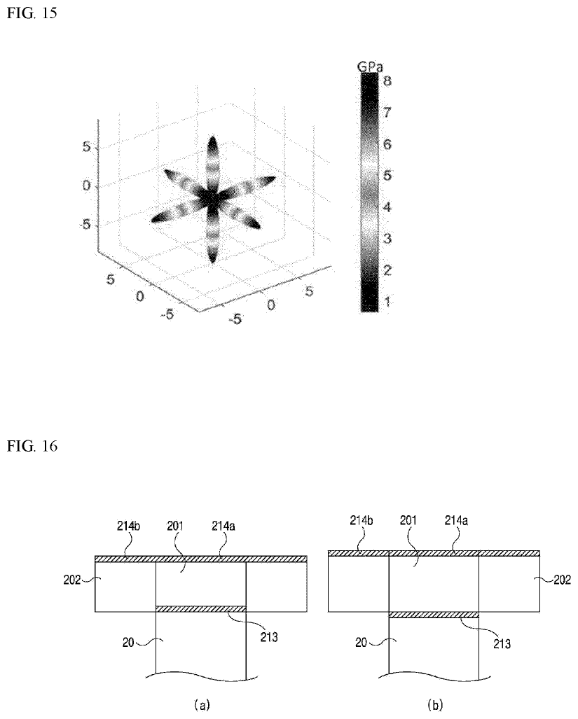

FIG. 15 is an image illustrating tensile compressive load characteristics of the sound wave delivery structure in FIG. 12.

As illustrated in FIG. 15, it can be seen that the unit structure cells 210 and 220 according to the present embodiment has a very high modulus of elasticity in an axial direction and great rigidity against a tensile compressive load. Therefore, the sound wave delivery structure 200 including the unit structure cells 210,220 is less affected by bending vibration of the front weight, and performance can be effectively achieved in an environment in which an axial tensile compressive load is large.

FIG. 16 is a view illustrating a first contact surface and a second contact surface of the sound wave delivery structure in FIG. 12.

As illustrated in FIG. 16, the sound wave delivery structure 200 may have a first contact surface 213 that comes into contact with the vibrating part 20 that generates sound waves. Based on a proceeding direction of a sound generated from the vibrating part 20, the first contact surface 213 may be the rear surface of the sound wave delivery structure 200.

It is preferable that the first contact surface 213 is formed in the form of a filled surface without an empty space. Therefore, since not only the compressive deformation of the first contact surface 213 can be prevented but also the sound wave delivery structure 200 and the vibrating part 20 may be in closer contact with each other, the sound wave delivery structure 200 may effectively deliver the vibration of the vibrating part 20 as sound waves.

The first contact surface 213 may be formed at the same height while connecting column portions at rear end sides of the plurality of unit structure cells disposed at a portion in contact with the vibrating part 20 in the sound wave delivery structure 200 (see FIG. 16A) or formed to further protrude rearward than the column portions at the rear end sides of the plurality of unit structure cells to have a thickness (see FIG. 16B).

A fastening member (e.g., a bolt) connecting the sound wave delivery structure 200 to the vibrating part 20 may be directly coupled to the first contact surface 213.

In addition, the sound wave delivery structure 200 may have second contact surfaces 214a and 214b formed at an opposite side of the first contact surface 213 and in contact with an external medium. The second contact surfaces 214a and 214b may include the second contact surface 214a formed at the central portion 201 and the second contact surface 214b formed at the edge portion 202. Based on the proceeding direction of the sound generated from the vibrating part 20, the second contact surfaces 214a and 214b may be front surfaces of the sound wave delivery structure 200. In addition, the external medium may be water.

It is preferable that the second contact surfaces 214a, 214b are formed in the form of a filled surface without an empty space. Therefore, since watertightness can be improved, a radiating area can be increased, an axial displacement of a radiating surface can be increased, and the external medium can be in closer contact, it is possible to maximize the radiated sound energy and effectively deliver the sound waves radiated from the sound wave delivery structure 200 to the external medium. In addition, the second contact surfaces 214a and 214b can prevent foreign substances included in the external medium from flowing into the sound wave delivery structure 200.

The second contact surfaces 214a and 214b may be formed at the same height while connecting column portions at front end sides of the plurality of unit structure cells disposed on the front surface portion of the sound wave delivery structure (see FIG. 16A) or formed to further protrude forward than the column portions at the front end sides of the plurality of unit structure cells to have a thickness (see FIG. 16B).

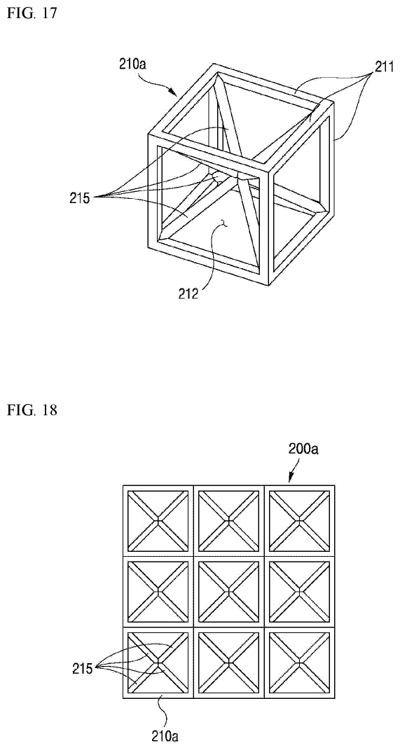

FIG. 17 is a view illustrating a first modified example of unit structure cells of the sound wave delivery structure in FIG. 12, and FIG. 18 is a front view illustrating the unit structure cells in FIG. 17.

As illustrated in FIGS. 17 and 18, a unit structure cell 210a may further include an auxiliary column portion 215. In other words, the unit structure cell 210a may have a three-dimensional truss-lattice structure with the auxiliary column portion 215 in the space portion 212.

The auxiliary column portion 215 may connect two separated corners and may be disposed to cross the space portion 212. Since the unit structure cell 210a may be reinforced in a diagonal direction by the auxiliary column portion 215, the sound wave delivery structure 200a with the auxiliary column portion 215 may reinforce rigidity against a shear force and a bending load. This type of unit structure cell 210a may be applied to both the central portion and the edge portion. However, the present invention is not necessarily limited to this example, and this type of the unit structure cell 210a may be used in combination with the unit structure cells 210 and 220 in the form described with reference to FIG. 12. For example, the unit structure cell 210a with the auxiliary column portion 215 may be used in the central portion 201, and the unit structure cell 220 without the auxiliary column portion 215 may be used in the edge portion 202. Alternatively, the unit structure cell 220 without the auxiliary column portion 215 may be used in the central portion 201, and the unit structure cell 210a with the auxiliary column portion 215 may be used in the edge portion 202.

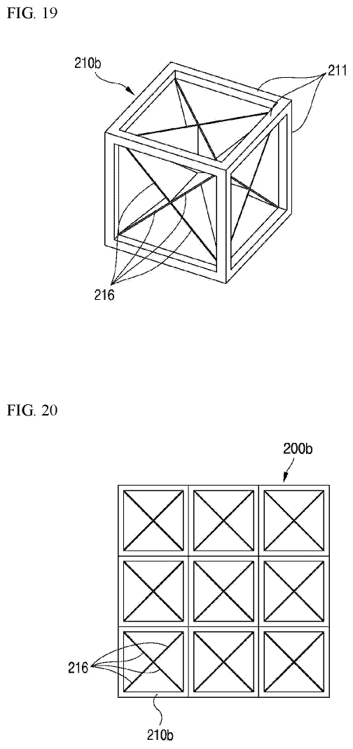

FIG. 19 is a view illustrating a second modified example of the unit structure cells of the sound wave delivery structure in FIG. 12, and FIG. 20 is a front view illustrating the unit structure cells in FIG. 19.

As illustrated in FIGS. 19 and 20, a unit structure cell 210b according to the present embodiment may further include a flat portion 216.

The flat portion 216 may be formed by connecting two corners selected from each surface of the unit structure cell 210b to a center of the space portion. Therefore, the unit structure cell 210b may have a three-dimensional plate-lattice structure.

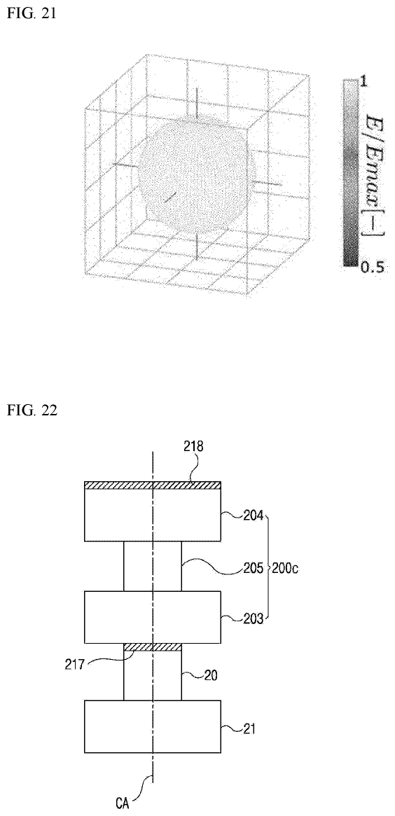

FIG. 21 is an image illustrating the characteristic of a modulus of elasticity of the sound wave delivery structure in FIG. 19, and as illustrated in FIG. 21, the sound wave delivery structure 200b including the unit structure cell 210b may have the same modulus of elasticity in all directions. In other words, since the sound wave delivery structure 200b including the unit structure cell 210b may have isotropic elasticity, the sound wave delivery structure 200b may have great rigidity against a shear force or a bending load.

Therefore, the sound wave delivery structure 200b including the unit structure cell 210b can stably achieve performance even in an environment in which the shear force is applied to the front weight or an environment in which the influence of bending vibration is greatly applied.

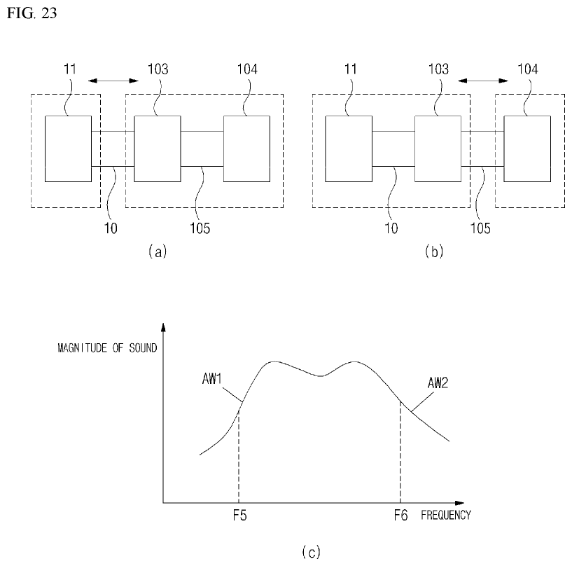

FIG. 22 is a view illustrating an example in which a sound wave delivery structure according to a third embodiment of the present invention is installed in an underwater sound sensor, and FIG. 23 is a view for describing that a broadband frequency is generated from the sound wave delivery structure according to the third embodiment of the present invention. In the second embodiment, there is a difference in that the sound wave delivery structure has a shape that is expanded in a radial direction of the central axis, while the sound wave delivery structure according to the present embodiment has a shape that is expanded in a central axis direction, other configurations such as the shape of the unit structure cell are the same as those of the second embodiment or may be applied in the same manner as the second embodiment, and repeated contents are omitted as much as possible.

As illustrated in FIGS. 22 and 23, a sound wave delivery structure 200c according to the present embodiment may include an intermediate mass 203, a front weight 204, and a connecting rod 205 connecting the intermediate mass 203 to the front weight 204, which are arranged in the first direction in which sound waves are delivered, that is, the central axis CA direction. The intermediate mass 203, the connecting rod 205, and the front weight 204 may be configured by consecutively arranging the unit structure cells in the first direction and the second direction crossing the first direction. In addition, all the intermediate mass 203, the connecting rod 205, and the front weight 204 may be formed integrally.

As the vibrating part 20 vibrates, when the connecting rod 205 and the front weight 204 disposed in front of the intermediate mass 203 vibrates with the intermediate mass 203 and the rear weight 21 vibrates, and thus a primary resonance is generated (see FIG. 23A) to radiate the first sound wave AW1, and the vibrating part 20 and the rear weight 21 disposed behind the intermediate mass 203 vibrates with the intermediate mass 203 and the front weight 204 vibrates, and thus a secondary resonance is generated (see FIG. 23B) to radiate the second sound wave AW2, a broadband band between a fifth frequency F5 and a sixth frequency F6 may be generated (see FIG. 23C).

It goes without saying that at least one type of unit structure cell among the unit structure cells described with reference to FIGS. 12, 17, and 19 may also be applied to the sound wave delivery structure 200c according to the present embodiment.

In addition, like the first contact surface 213 and the second contact surfaces 214a and 214b described with reference to FIG. 16, a third contact surface 217 formed between the intermediate mass 203 and the vibrating part 20 disposed at one side of the intermediate mass 203 may be formed as a filled contact surface without an empty space. In addition, since a fourth contact surface 218 formed between the front weight 204 and the external medium provided at the other side of the front weight 204 may be formed as a filled contact surface without an empty space, the effect described with reference to FIG. 16 can also be achieved in the present embodiment.

In addition, all the unit structure cells of the intermediate mass 203, the front weight 204, and the connecting rod 205 may be formed in the same size or each may be formed in a different size, or various applications, such as forming at least some of the unit structure cells in the same size, are possible. A density design of the unit structure cell can be appropriately implemented in a process of designing the sound wave delivery structure 200c to implement the required impedance.

The above description of the present invention is for illustrative purpose, and those skilled in the art to which the present invention pertains will be able to understand that the present invention may be easily modified in other specific forms without changing the technical spirit or essential features thereof. Therefore, it should be understood that the above-described embodiments are illustrative and not restrictive in all respects. For example, each component described in a singular form may be implemented separately, and likewise, components described as being implemented separately may also be implemented in a combined form.

The scope of the present invention is defined by the claims to be described below, and all changes or modifications derived from the meaning and scope of the claims and equivalent concepts thereof should be construed as being included in the scope of the present invention.

### INDUSTRIAL APPLICABILITY

The present invention can be industrially used in a technical field of a sound transducer for detecting a position of a target using sound waves in water.

1. A sound wave delivery structure comprising:
a unit structure cell formed in a three-dimensional shape and including column portions formed in areas corresponding to sides thereof, and a space portion formed in an inner area surrounded by the column portions,
wherein the unit structure cell is provided as a plurality of unit structure cells and disposed consecutively in a first direction in which sound waves are delivered and a second direction crossing the first direction.

2. The sound wave delivery structure of claim 1, wherein the unit structure cell is formed in a rectangular parallelepiped shape.

3. The sound wave delivery structure of claim 2, wherein the unit structure cell further includes an auxiliary column portion connecting two separated corners and disposed to cross the space portion.

4. The sound wave delivery structure of claim 2, wherein the unit structure cell further includes a flat portion formed to connect two corners selected from each surface to a center of the space portion.

5. The sound wave delivery structure of claim 1, further comprising a first contact surface in contact with a vibrating part that generates sound waves,
wherein the first contact surface is formed in the form of a filled surface without an empty space.

6. The sound wave delivery structure of claim 5, wherein a second contact surface of the sound wave delivery structure formed at an opposite side of the first contact surface and in contact with an external medium is formed in the form of a filled surface without an empty space.

7. A sound wave delivery structure comprising:
a unit structure cell formed in a three-dimensional shape and including column portions formed in areas corresponding to sides thereof, and a space portion formed in an inner area surrounded by the column portions,
wherein the unit structure cell is provided as a plurality of unit structure cells and disposed consecutively in a first direction in which sound waves are delivered and a second direction crossing the first direction, and
partitioned into a central portion formed within a predetermined distance from a center axis, and an edge portion provided at a position far from the central portion with respect to the center axis, and
a unit structure cell disposed at the central portion and a unit structure cell disposed at the edge portion among the plurality of unit structure cells are different.

8. The sound wave delivery structure of claim 7, wherein the unit structure cell is formed in a rectangular parallelepiped shape.

9. The sound wave delivery structure of claim 7, wherein a cross-sectional area of the column portion of the unit structure cell disposed at the central portion is larger than a cross-sectional area of the column portion of the unit structure cell disposed at the edge portion.

10. The sound wave delivery structure of claim 7, wherein the unit structure cell disposed at the central portion and the unit structure cell disposed at the edge portion have different sizes.

11. The sound wave delivery structure of claim 7, wherein a first contact surface formed between the sound wave delivery structure and a vibrating part disposed at one side of the sound wave delivery structure is formed in the form of a filled surface without an empty space.

12. The sound wave delivery structure of claim 7, wherein a second contact surface formed between the sound wave delivery structure and an external medium provided at the other side of the sound wave delivery structure is formed in the form of a filled surface without an empty space.

13. The sound wave delivery structure of claim 7, wherein the unit structure cell further includes an auxiliary column portion connecting two separated corners and disposed to cross the space portion.

14. The sound wave delivery structure of claim 7, wherein the unit structure cell further includes a flat portion formed to connect two corners selected from each surface to a center of the space portion.

15. A sound wave delivery structure comprising:
a unit structure cell formed in a three-dimensional shape and including column portions formed in areas corresponding to sides thereof, and a space portion formed in an inner area surrounded by the column portions,
wherein an intermediate mass, a front weight, and a connecting rod connecting the intermediate mass to the front weight, which are arranged in a first direction in which sound waves are delivered, are formed, and
the intermediate mass, the connecting rod, and the front weight are configured by consecutively arranging the unit structure cells in the first direction and a second direction crossing the first direction.

16. The sound wave delivery structure of claim 15, wherein the unit structure cell is formed in a rectangular parallelepiped shape.

17. The sound wave delivery structure of claim 15, wherein a third contact surface formed between the intermediate mass and a vibrating part disposed at one side of the intermediate mass is formed in the form of a filled contact surface without an empty space.

18. The sound wave delivery structure of claim 15, wherein a fourth contact surface formed between the front weight and an external medium provided at the other side of the front weight is formed in the form of a filled contact surface without an empty space.

19. The sound wave delivery structure of claim 15, wherein the unit structure cell further includes an auxiliary column portion connecting two separated corners and disposed to cross the space portion.

20. The sound wave delivery structure of claim 15, wherein the unit structure cell further includes a flat portion formed to connect two corners selected from each surface to a center of the space portion.
